(19) United States
(12) Patent Application Publication
(10) Pub. No.: US 2008/0118849 A1
(43) Pub. Date: May 22, 2008

(54) Reflective optical system for a photolithography scanner field projector

(76) Inventors: Manish Chandhok, Beaverton, OR (US); Russell Hudyma, San Ramon, CA (US)

Correspondence Address: INTEL/BLAKELY, 1279 OAKMEAD PARKWAY, SUNNYVALE, CA, 94085-4040, US

(21) Appl. No.: 11/603,811

(22) Filed: Nov. 21, 2006

(51) Int. Cl. G03F 1/00; G03B 27/54

(52) U.S. Cl. 430/5

(57) ABSTRACT

A reflective optical system for a photolithography scanner field projector is described. In one example, the optical projection system has at least eight reflecting surfaces for imaging a reflection of a photolithography mask onto a wafer and the system has a numerical aperture of at least 0.5.

### BACKGROUND

1. Field

The description relates to a field projection system for photolithography, and, in particular to a reflective optical reflection system with an obscuration for an enhanced numerical aperture and other improved characteristics.

2. Related Art

To increase the number of transistors, diodes, resistors, capacitors, and other circuit elements on an integrated circuit chip, these devices are placed closer and closer together. This requires that each device be made smaller. Current manufacturing technologies use laser light with a wavelength of 193nm for photolithography. These are referred to as Deep Ultraviolet (DUV) systems. These systems are capable of reliably producing features that are about 100 nm across and at best perhaps 50 nm across. One obstacle to producing still smaller features is the wavelength of the light being used. The next step that has been proposed is to use light of 4 nm-30 nm referred to as Extreme Ultraviolet (EUV) light. Depending on the rest of the system and process parameters, this light may allow features to be created that are as small as 10 nm to 20 nm across, much less than the current 50 nm-100 nm.

The smaller size of the features is a result of the improvement in resolution. The resolution of a photolithography system is proportional to the wavelength of the light divided by the numerical aperture of the illumination system's projection optics. As a result, the resolution can be improved by either decreasing the wavelength of the light used, or by increasing the numerical aperture (NA) of the photolithography projection optics, or both.

One popular wavelength for proposed EUV photolithography is 13.5 nm. All known materials absorb light at this frequency. As a result, the projection optics cannot be made using transparent lenses. The proposed projection optics are accordingly based on using curved mirrors. For EUV light, however, the best mirrors so far developed reflect only about 70% of the light that shines on them. The other 30% of the light is absorbed by the mirror.

These EUV projection optics mirrors are made by applying a multilayer coating to a silicon substrate. The multilayers are made up of 40 or more alternating layers of either Mo and Si, or Mo and Be. The multilayers rely on a periodic structure to build a reflected wavefront between the coatings. The reflectivity of the surface is greatly affected by the angle at which light hits the surface, the temperature and the wavelength of the light. For angles of incidence, reflectivity is highest when light hits the mirror directly, that is perpendicular to the mirror surface. The more the light diverges from the perpendicular, the lower the reflectivity of the mirror to that light. When angles of incidence are over twenty degrees, the increase in the loss of light is significant. This greatly limits the possible designs of an optical system. Projection optical designs that work well for DUV may not work at all for EUV due to high angles of incidence.

The numerical aperture (NA) of a photolithography scanner is limited in part by the number of mirrors in the projection optics. A six mirror system may have an NA of 0.25 and an eight mirror system may have an NA of 0.4. However, with EUV illumination, the best known mirrors are only partially reflective. Accordingly an eight mirror system may reduce the amount of light that comes through the mirror system in half compared to a six mirror system. More mirrors either requires longer exposure times or a brighter light source. Longer exposure times can significantly affect the time it takes to produce a microelectronic device. A brighter light source presents other difficulties with EUV light due to the extreme heat caused by absorption of the light and the destructive impact of the light itself. As a result, an eight mirror system has been considered impractical.

### BRIEF DESCRIPTION OF THE DRAWINGS

Embodiments of the present invention may be understood more fully from the detailed description given below and from the accompanying drawings of various embodiments of the invention. The drawings, however, should not be taken to be limiting, but are for explanation and understanding only.

FIG. 1A shows a ray tracing diagram in the x-z plane of an example reflective projection optical system for photolithography according to an embodiment of the invention;

FIG. 1B shows a ray tracing diagram in the x-y plane of the example reflective projection optical system of FIG. 1A;

FIG. 2 shows a view down the optical axis of the projection optical system of FIG. 1A showing two obscurations;

FIG. 3 is a diagram of a distortion and aberration analysis of the projection optical system of FIG. 1A;

FIG. 4 is a table providing a prescription for the projection optical system of FIG. 1A;

FIG. 5 is a table providing specification data for the projection optical system of FIG. 1A;

FIG. 6 is a table providing mean incidence angles for the projection optical system of FIG. 1A;

FIG. 7 is a table providing wavefront analysis for the projection optical system of FIG. 1A;

FIG. 8A shows a ray tracing diagram in the x-z plane of a second example reflective projection optical system for photolithography according to an embodiment of the invention;

FIG. 8B shows a ray tracing diagram in the x-y plane of the example reflective projection optical system of FIG. 8A;

FIG. 9 shows a view down the optical axis of the projection optical system of FIG. 8A showing two obscurations;

FIG. 10 is a diagram of a distortion and aberration analysis of the projection optical system of FIG. 8A;

FIG. 11 is a table providing a prescription for the projection optical system of FIG. 8A;

FIG. 12 is a table providing specification data for the projection optical system of FIG. 8A;

FIG. 13 is a table providing mean incidence angles for the projection optical system of FIG. 8A;

FIG. 14 is a table providing wavefront analysis for the projection optical system of FIG. 1;

FIG. 15 shows a ray tracing diagram in the x-z plane of a third example reflective projection optical system for photolithography according to an embodiment of the invention;

FIG. 16 shows a view down the optical axis of the projection optical system of FIG. 15 showing two obscurations;

FIG. 17 is a table providing mean incidence angles for the projection optical system of FIG. 15; and

FIG. 18 is an example stepper for EUV photolithography suitable for use with embodiments of the present invention.

### DETAILED DESCRIPTION

An eight mirror optical projection system for EUV light that can achieve a NA of 0.5 is described. This doubles the resolution as compared to other six and eight mirror systems. The higher NA results in a significantly higher etendue (collected light) for the system offsetting the light lost by absorption in the two additional mirrors. An obscuration in the eight mirror system is also described to help in maintaining low incident angles throughout the system. Annular collection optics may be used to compensate for light lost by the obscuration.

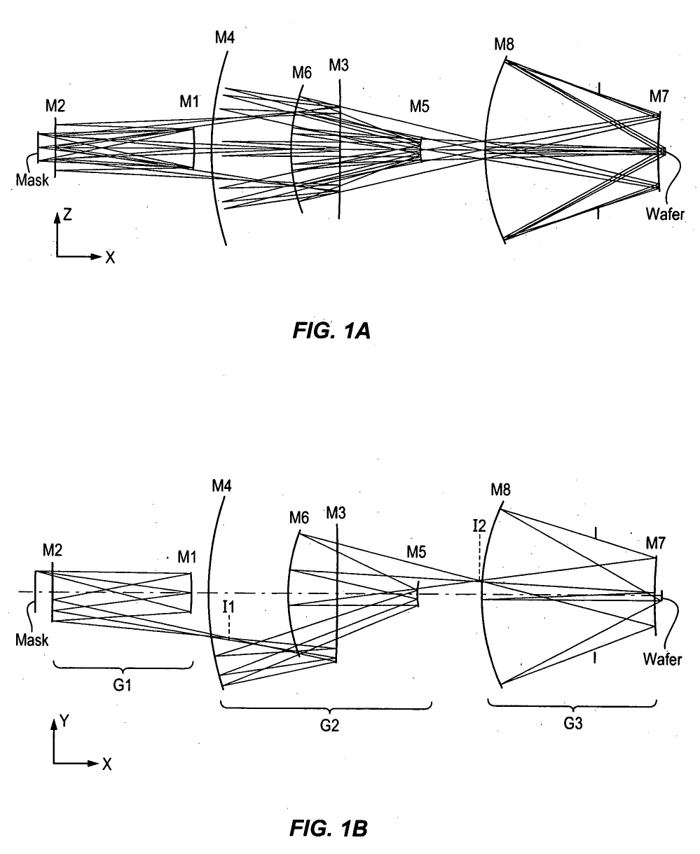

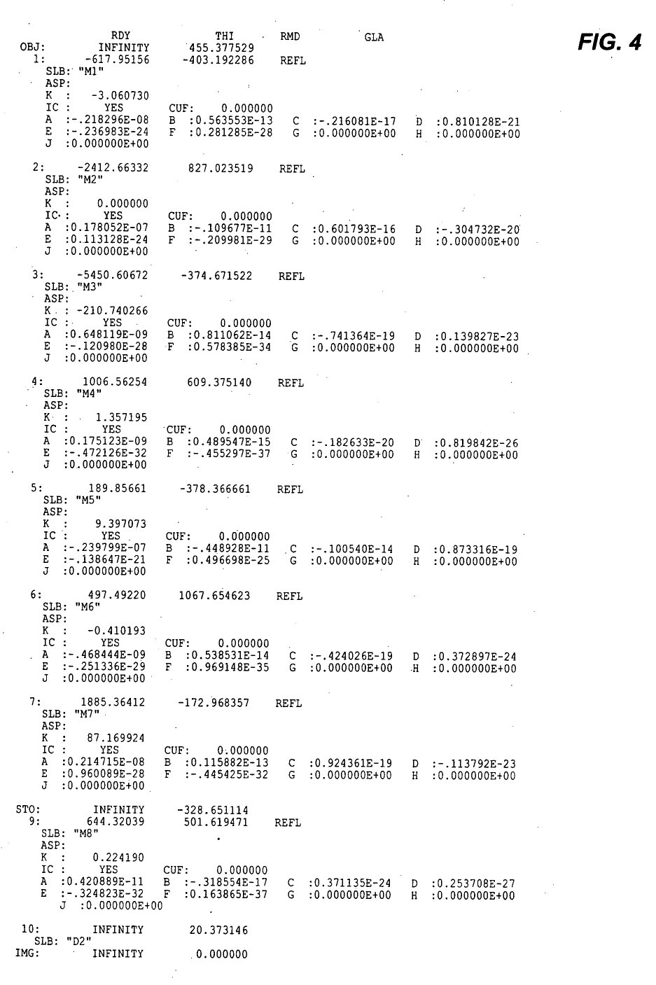

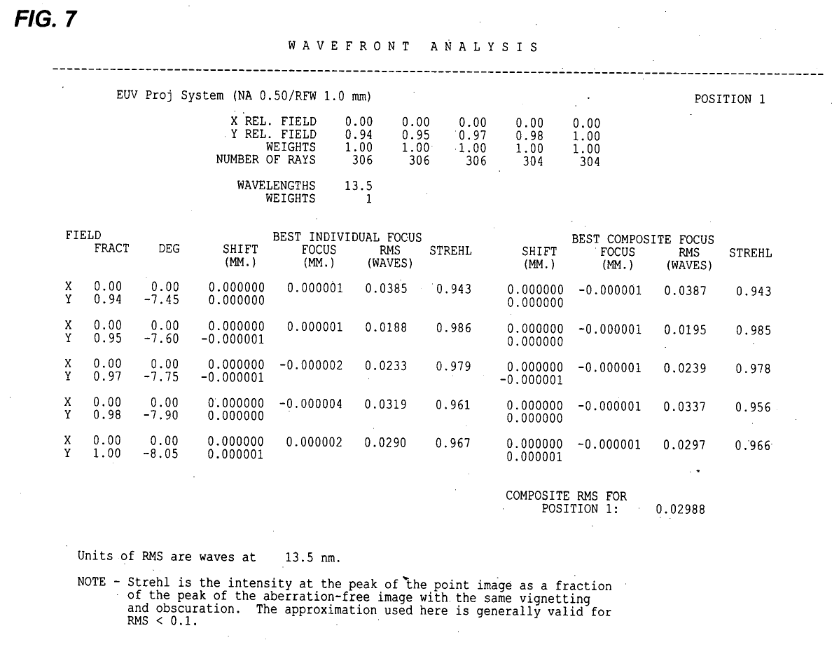

FIG. 1A shows a ray tracing diagram of an example of a reflective projection optical system in the x-z plane. FIG. 1B shows the same system in the x-y plane. This system is suitable for EUV photolithography projection optics according to one embodiment of the invention. A prescription for each of the mirrors in terms of radii, aspheric prescription, and the axial separation of the mirrors of the system of FIGS. 1A and 1B is shown in FIG. 4. The mean incidence angles of the light striking each mirror is provided in FIG. 6 and a wavefront analysis of the mirror system is provided in FIG. 7.

The reflective optical system of FIGS. 1A and 1B is an obscured eight-mirror system design that can achieve a numerical aperture of 0.50 with a ring field width between 1-2 mm. The mask is at the far left of the diagram and the wafer is at the far right. The light source and collection optics to illuminate the mask are not shown. Of the eight mirrors, mirrors M7 and M8 have a small obscuration in the form of a hole through the surface of the mirror.

The mask may have a square imaging surface measuring about 6 inches (150 mm) on each side. The projected image field may then be about 1 mm×20 mm (scan×cross-scan), which is a desirable field for a stepping scanner.

The resolution of an optical lithography system is customarily quoted by the coherent approximation of Rayleigh's equation,

R=k1λ/NA

which expresses the resolution, R in terms of the smallest resolvable half-pitch (one half of the minimum line plus minimum space) as a function of the unit-less Rayleigh constant k1, the wavelength of the light, λ, and, the numerical aperture of the exposure system, NA. The k1 value is used as a measure of the quality of the lithographic process based on chemical and other aspects of the lithography processing. Assuming a k1 factor of 0.5, this design achieves a minimum resolution provided by k1λ/NA as 0.5×13.5 nm/0.5=13.5 nm. Special printing techniques and alternate illumination schemes may allow this to be increased to below 10 nm. This is close to the limit of operation for silicon semiconductor materials.

In the projection system of FIGS. 1A and 1B, from long conjugate to short conjugate, the first mirror is concave, the second convex, the third concave, the fourth concave, the fifth convex, the sixth concave, the seventh convex, and the eighth concave. Denoting a concave mirror with a ‘P’ (positive optical power) and a convex mirror with an ‘N’ (negative optical power), the configuration of the first embodiment may be described as “PNPPNPNP”.

Mirrors M1 and M2 work together as a first imaging group G1. Group G1 forms an intermediate image I1 of the mask after mirror M2. Mirrors M3, M4, M5, and M6 form another imaging group G2 to form a second intermediate image I2 of the first intermediate image between M6 and M7. This intermediate image is relayed by the third imaging group G3 consisting of mirrors M7 and M8 onto the wafer.

Group G3 relays the second intermediate image 12 formed by Group G2 to the wafer at the proper reduction, which in this example is a fourfold reduction. The second intermediate image I2 is roughly midway between mirrors M6 and M7 This location far from either mirror helps to reduce the incidence angle of the chief ray and provides more clearance or space between the mirrors. Similarly the first intermediate image I1 is roughly midway between mirrors M2 and M3, providing similar benefits.

The back working distance is small (about 1-2 mm), but sufficient for current immersion steppers operating under similar conditions. This is enabled in part by the aspect ratio of mirror M7 of 20:1. The chief ray angle at the mask is in the range of about eight degrees which affects the Horizontal-Vertical bias due to shadowing effects. However, this may be easily compensated by mask bias.

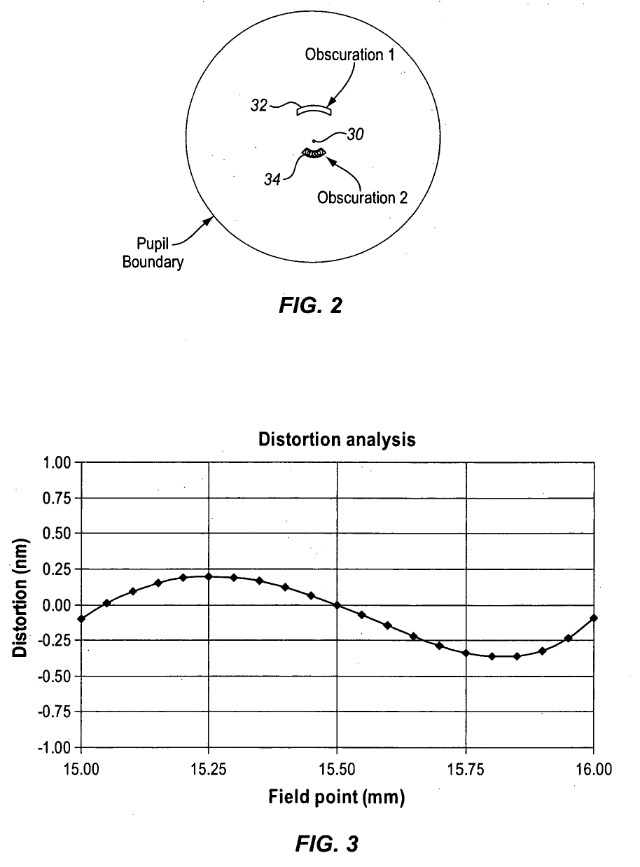

FIG. 2 shows a view down the optical axis 30 of the projection optical system of FIG. 1A showing the two obscurations. The upper slit 32 is the obscuration in M8. Since the surface of M8 is near a virtual image from M6, the complete image is able to pass through the small obscuration in M8. Similarly, since the lower slit 34 in M7 is near the actual image from M8 onto the wafer, a small slit is able to pass the complete image. In the present example, the slits are approximately 1-2 mm wide and 26 mm across. Light passes through the hole 32 in mirror M7 in its path from mirror M8 to the wafer. Light passes though the hole 34 in mirror M8 in its path from mirror M6 to M7. The obscurations are so small as to be unlikely to have a material impact on partially coherent imagery.

Pupil plane obscurations may affect imaging. A small projection lens with only a 10% obscuration in area (31.6% in linear dimensions) can block diffracted orders of light that would otherwise pass through the center of the pupil. This can seriously degrade the quality of the image. To overcome this blocking of the diffracted orders, the diffracted orders may be directed at off-axis angles, as shown in the drawings.

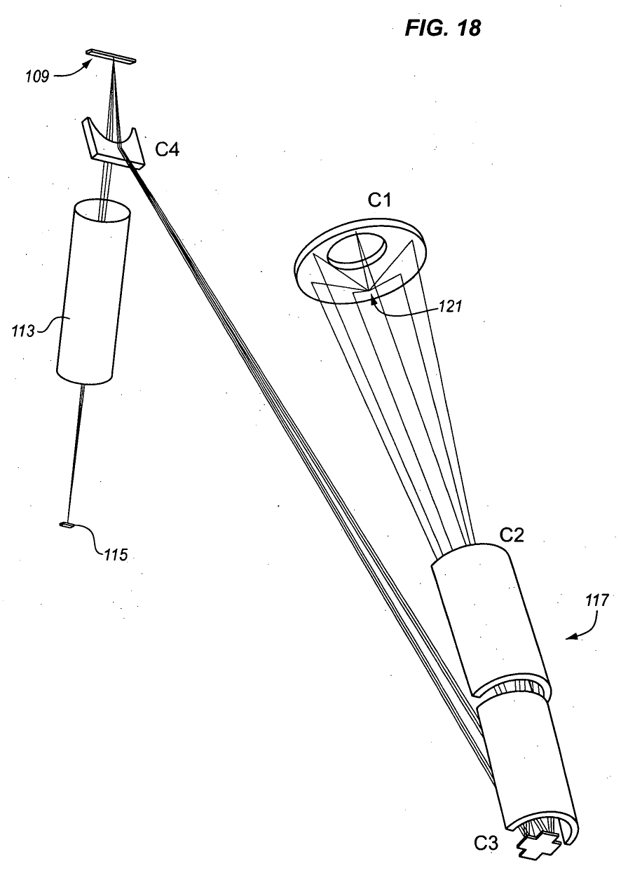

In order to reduce light loss with a such a central obscuration, an annular illumination pattern, as compared to a disk illumination pattern, may be used. Such a pattern may have a central roughly circular darkened portion surrounded by a roughly annular bright portion. The bright portion has a inner circular circumference at the outer circumference of the dark portion and an outer circular circumference within the imaging field of the projection optical system This will allow the light intensity to be increased outside the obscurations, decreased through the obscurations and as a result will increase the contrast of the resulting image on the wafer The annular illumination pattern may be produced by the collection optics (see e.g. 117, FIG. 18).

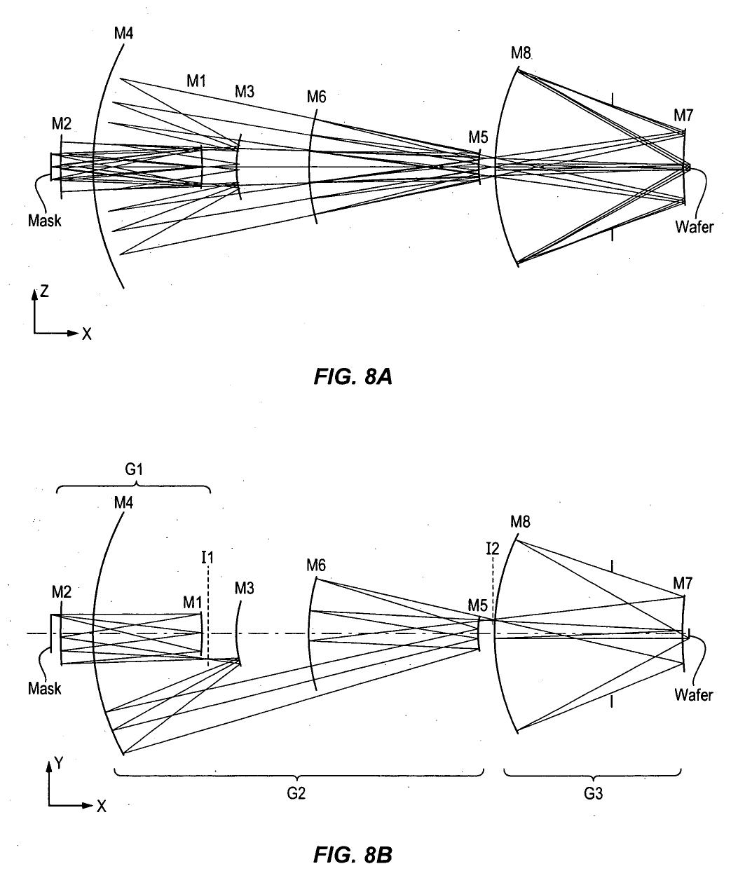

An annular illumination pattern or off-axis illumination scheme or collection optical system may be combined with the projection optics of FIGS. 1A and 1B and with that of FIGS. 8A and 8B as well. The illumination pattern will compensate at least in part for the obscuration described above in those systems.

FIG. 3 shows a distortion and aberration analysis done after a ray-tracing optimization showing a well corrected design. The maximum range of distortion across the entire image field is no more than about 0.45 nm. The changes in displacement are even and gradual. Reduction ratios in the range of 4:1 to 5:1 are possible. This low distortion is well within the required ranges for photolithography with EUV light.

In FIG. 4, the prescription has been listed in Code V® format (of Optical Research Associates of Pasadena, Calif.). The mirrored surfaces are numbered as OBJ:1-8 in the same order as M1-M8 in the figures. After the surface number, there are two additional entries that list the radius of curvature (R) and the vertex to vertex spacing between the optical surfaces. The ASP entry after each surface denotes a rotationally symmetric conic surface with higher-order polynomial deformations. The aspheric profile is uniquely determined by its K, A, B, C, D, E, F, G, H, and J values.

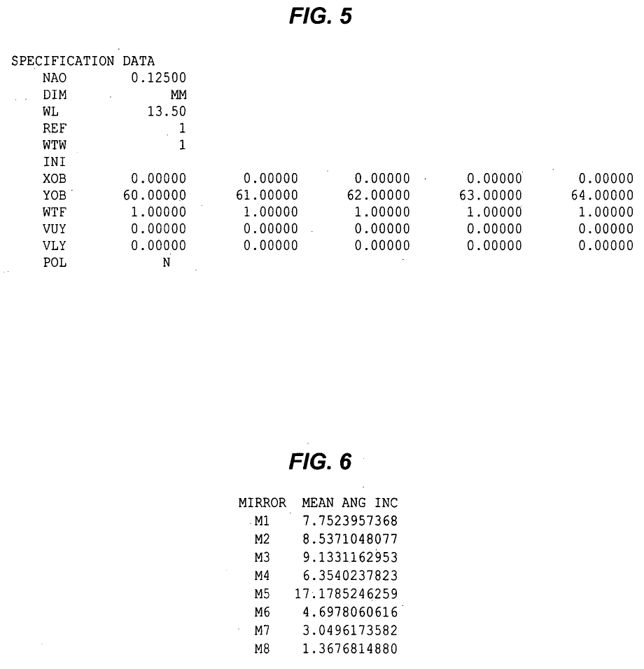

Specification data is provided in FIG. 5. The numerical aperture at the object (NAO) is 0.125 radians; this specification sets the angular divergence of the imaging bundles at the mask. The YOB designation defines the extent of the ring field in the scan dimension.

FIG. 6 shows mean incidence angles. The incidence angles of the imaging bundle are quantified with respect to the “chief ray.” The chief ray from a given field point is the ray that emanates from this field point and passes through the center of the aperture stop. To a good approximation, the mean angle of incidence of any mirror can be estimated by the angle of incidence of the chief ray that emanates from the field point that lies in the center of the ring field. To be more precise, this field point lies in the tangential plane of the projection system at the midpoint of the radial extremum of the arcuate field.

As mentioned above, mirrors so far developed for EUV light use multilayer coatings. However, the reflectivity of these coatings decreases more rapidly as the incident angle increases. In other words, each additional increase in incident angle has a greater effect. That is, projection systems are more susceptible to phase errors induced by the multilayer reflective coatings when the mean angle of incidence is greater. Therefore, for best results with multilayer coatings, the mean incidence angle at the mirrors of the projection lithography system should be minimized. Angles of twelve degrees and less work well. Angles above twenty degrees work very poorly. Moreover, the angular deviation of the imaging bundles at any point on the mirror should also be minimized in order to reduce both phase and amplitude errors imparted to the imaging bundle by the multilayer reflective coatings. FIG. 6 shows mean incidence angles that, with one exception are well under ten degrees. Even the one exceptional case, M5 has a mean incidence angle well under twenty degrees.

FIG. 7 shows a wavefront analysis of the optical system in which the composite RMS (Root Mean Square) position for the system is determined to be about 0.03. This is also within the requirements for photolithography.

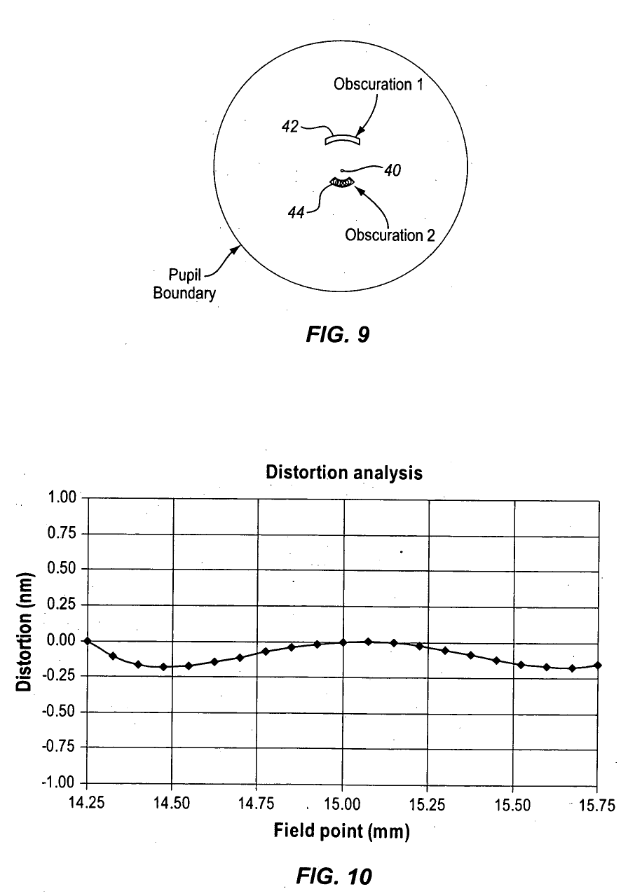

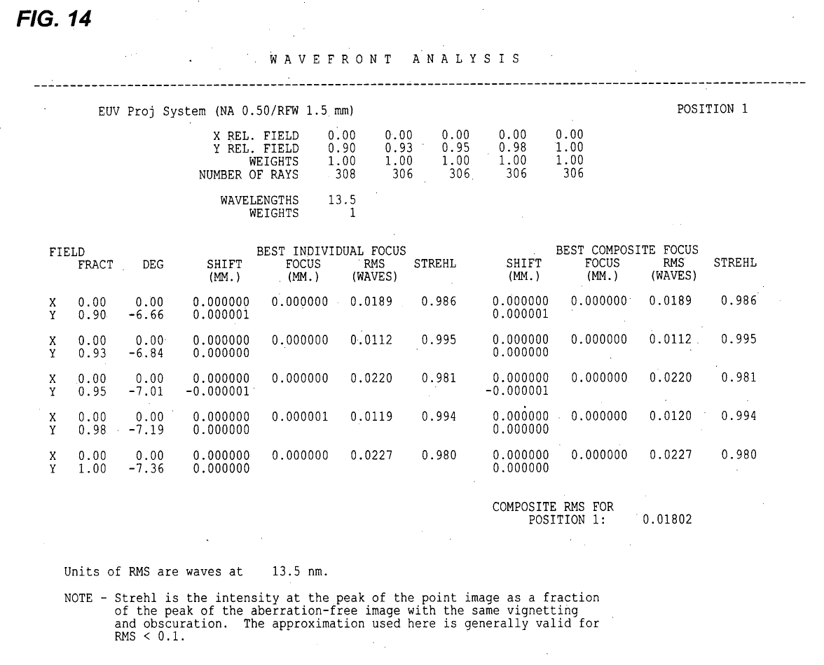

FIGS. 8A and 8B show a ray tracing diagram of another example embodiment of the present invention. FIG. 8A shows the system in the x-z plane. FIG. 8B shows the system in the x-y plane. A prescription for each of the mirrors of this system in terms of radii, aspheric prescription, and the axial separation is presented in FIG. 10. The mean incidence angles of the light striking each mirror is provided in FIG. 13 and a wavefront analysis of the mirror system is provided in FIG. 14.

The reflective optical system of FIGS. 8A and 8B is also an obscured eight-mirror system design that can achieve a numerical aperture of 0.50 with a ring field width between 1-2 mm. The mask is at the far left of the diagram and the wafer is at the far right. The light source and collection optics to illuminate the mask are again not shown. Of the eight mirrors; mirrors M7 and M8 have a small obscuration in the form of a hole through the surface of the mirror.

The system of FIGS. 8A and 8B also show a numerical aperture of 0.5 and a minimum resolution of 13.5 nm. However, with lower angles of incidence and less distortion, the performance is even higher than that of FIGS. 1A and 1B.

In the projection system of FIGS. 8A and 8B, from long conjugate to short conjugate, the first mirror is concave, the second concave, the third convex, the fourth concave, the fifth convex, the sixth concave, the seventh convex, and the eighth concave. Denoting a concave mirror with a ‘P’ (positive optical power) and a convex mirror with an ‘N’ (negative optical power), the configuration of the first embodiment may be described as “PPNPNPNP”.

As in the example of FIGS. 1A and 1B, mirrors M1 and M2 work together as a first imaging group G1. Group G1 forms an intermediate image I1 of the mask after mirror M2. Mirrors M3, M4, M5, and M6 form another imaging group G2 to form a second intermediate image of the mask I2 between M6 and M7. This intermediate image is relayed by the third imaging group G3 consisting of mirrors M7 and M8 onto the wafer.

The first and second intermediate images I1, I2 are roughly midway between mirrors. The closest mirrors are M2 and M3, and M6 and M7, respectively. The distance from both mirrors helps to reduce the incidence angle of the chief ray and provides increased clearance.

FIG. 9 shows a view down the optical axis 40 of the projection optical system of FIGS. 8A and 8B showing the obscurations in M7 and M8. The upper slit 42 is the obscuration in M8, positioned near the second intermediate image 12 of the system. The lower slit 44 in M7 is near the wafer, a small slit is able to pass the complete image. In the present example, the slits are again approximately 1-2 mm wide and 26 mm across. Light passes through the hole 32 in mirror M7 in its path from mirror M8 to the wafer. Light passes though the hole 34 in mirror M8 in its path from mirror M6 to M7. The obscurations are so small as to be unlikely to have a material impact on partially coherent imagery.

FIG. 10 shows a distortion and aberration analysis done after a ray-tracing optimization. FIG. 10 shows even less distortion than the example of FIGS. 1A and 1B. The maximum range of distortion across the entire image field is less than 0.2 nm.

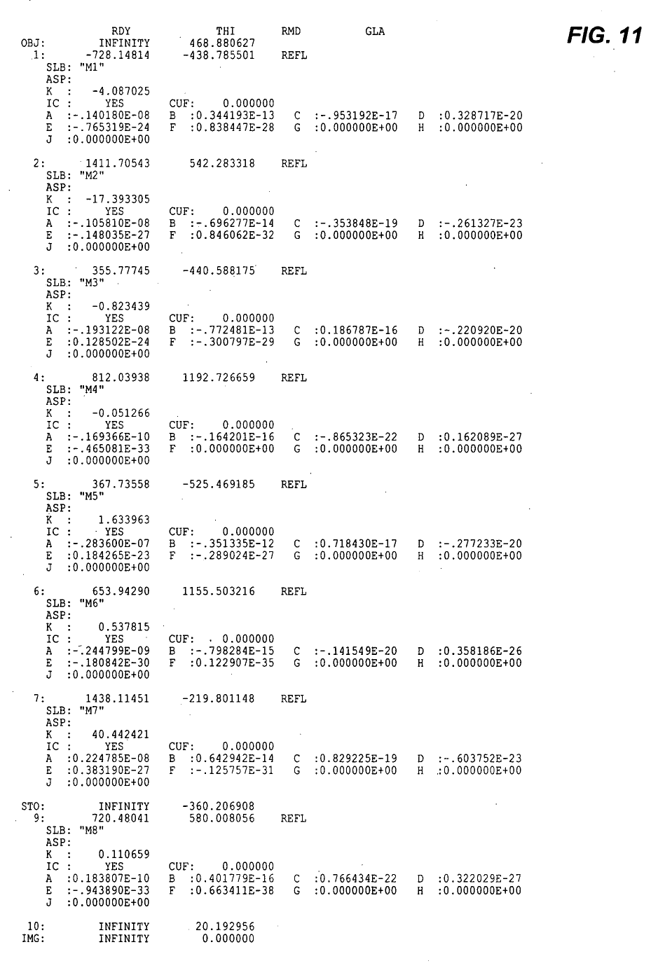

FIG. 11 shows an example prescription listed in Code V® format. The format and the structure is the same as for FIG. 4.

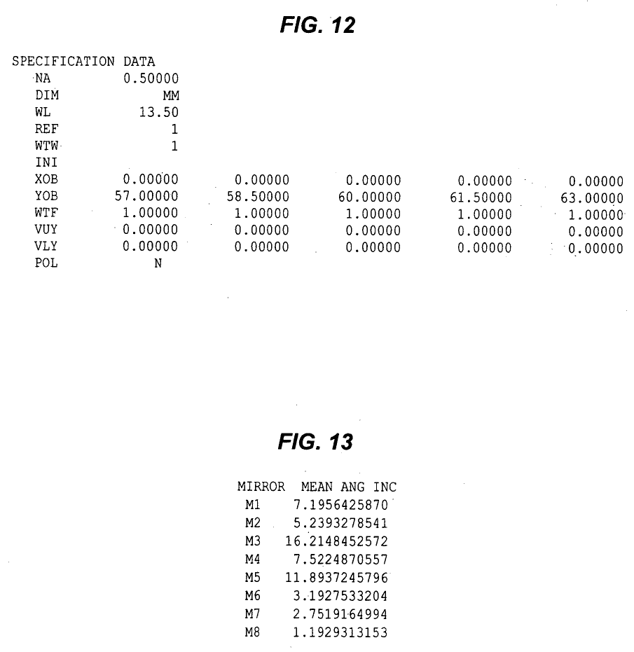

FIG. 12 shows specification data in the same format as FIG. 5.

FIG. 13 shows mean incidence angles in the same way as for FIG. 6. In FIG. 12 with two exceptions, the mean incidence angles are no more than 7.5 degrees. The two exceptions, M3 and M5, are still well under twenty degrees. The highest angle of incidence is still significantly less than the highest angle of incidence for the example of FIGS. 1A and 1B. The system of FIGS. 8A and 8B can therefore be expected to show less light loss and more accurate imaging than that of FIGS. 1A and 1B.

FIG. 14 shows a wavefront analysis of the optical system in which the composite RMS (Root Mean Square) position for the system is determined to be about 0.018. This is still lower than for FIGS. 1A and 1B.

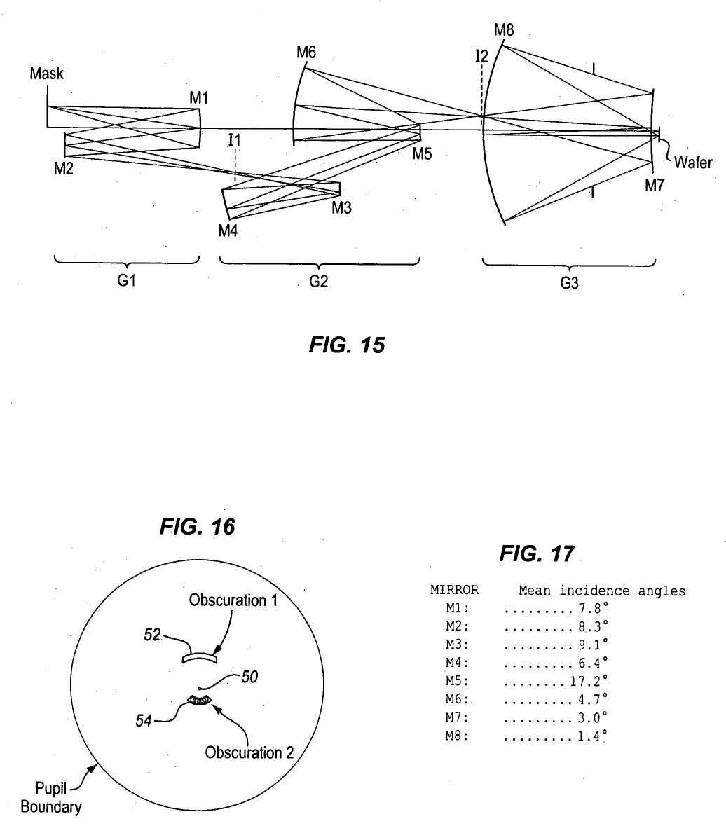

FIG. 15 shows a third embodiment of the present invention. FIG. 15 shows the system in the x-z plane. The reflective optical system of FIG. 15 is also an obscured eight-mirror system design that can achieve a numerical aperture of 0.50 with a ring field width between 1-2 mm. The mask is at the far left of the diagram and the wafer is at the far right. The light source and collection optics to illuminate the mask are again not shown. Of the eight mirrors, mirrors M7 and M8 again have a small obscuration in the form of a hole through the surface of the mirror.

In the projection system of FIG. 15, from long conjugate to short conjugate, the first mirror is concave, the second concave, the third convex, the fourth concave, the fifth convex, the sixth concave, the seventh convex, and the eighth concave. Denoting a concave mirror with a ‘P’ (positive optical power) and a convex mirror with an ‘N’ (negative optical power), the configuration of the third embodiment may be described as “PPNPNPNP”.

Again, mirrors M1 and M2 work together as a first imaging group G1. Group G1 forms an intermediate image I1 of the mask after mirror M2. Mirrors M3, M4, M5, and M6 form another imaging group G2 to form a second intermediate image of the mask I2 between M6 and M7. This intermediate image is relayed by the third imaging group G3 consisting of mirrors M7 and M8 onto the mask.

FIG. 16 shows a view of the obscurations similar to FIGS. 2 and 9. Again the obscurations are in M7 and M8. The upper slit 52 with respect to the optical axis 50 is the obscuration in M8, positioned near the second intermediate image 12 of the system. The lower slit 54 in M7 is near the wafer. In the present example, the slits are approximately the same size and shape as in FIGS. 2 and 9.

FIG. 17 shows mean incidence angles in the same way as for FIGS. 6 and 13. The mean incidence angles are all under 20 degrees with all but one incidence angle being under 10 degrees.

The system can otherwise be characterized as having: an RMS field composite wavefront error of 30.3 ml; a total distortion of less than 0.3 nm; a field curvature of less than 1.0 nm with no astigmatism or FC; a chief ray angle at the mask of 7.75 degrees and a telecentricity at the wafer of less than 1.0 mrad. These characteristics are very similar in all three described embodiments.

The embodiments of the invention described above use 8 mirrors as compared to the 6 mirrors common in some previous designs. At EUV wavelengths, with 30% absorption, the additional 2 mirrors cause a significant amount of additional light to be absorbed. However, the designs described above use the 2 additional mirrors for a significant reduction in incidence angles and for a significant increase in numerical aperture NA and in etendue. As a result the transmission of light through the projection optics system is actually increased.

Popular current projection optics designs provide a 0.25 NA with a 2 mm×26 mm scanning field using 6 mirrors. That compares to a 0.5 NA with a 1.5 mm×20 mm scanning stage and 8 mirrors. Etendue can be determined by Eₒₚₜ=w×h×π×σ²×NA². With σ being 0.5 for the 6 mirror system and 0.6 for the 8 mirror system the etendue is 2.55 for the 6 mirror system as compared to 8.48 for embodiments of the present invention.

The 8-mirror systems of the present invention accordingly offers a 3.33 times increase in étendue over current 6 mirror EUV projection systems. On the other hand, due to the 2 extra bounces, the throughput is decreased by a factor of 0.49 (0.7×0.7). In other words the amount of light transmitted through 8 mirrors as compared to 6 mirrors is reduced in half.

The transmission, however, is still increased by a factor of 1.63 (63%). The increase in étendue (area-solid angle product) overcomes the losses induced by adding 2 more reflections at 70% each. The increase in transmission can be quickly determined by multiplying the etendue increase by the reflection loss (3.33×0.49=1.63).

FIG. 18 shows a conventional architecture for a semiconductor fabrication machine, in this case, an optical lithography machine, that may be used to hold a mask and expose a wafer in accordance with embodiments of the present invention. The stepper may be enclosed in a sealed vacuum chamber (not shown) in which the pressure, temperature and environment may be precisely controlled. The stepper has an illumination system including a light source 121, such as an excimer laser or Xenon gas discharge chamber, and an optical collection system 117 to focus the light on the wafer. A reticle scanning stage (not shown) carries a mask 109. The light from the lamp is transmitted onto the mask and the light transmitted through the mask is focused further by a projection optical system 113 such as one of the optical systems described above with, for example, a four-fold reduction of the mask pattern onto the wafer 115.

The stepper of FIG. 18 is an example of a fabrication device that may benefit from embodiments of the present invention. Embodiments of the invention may also be applied to many other photolithography systems. The stepper is shown diagrammatically. The relative positions of the various components may be changed.

A lesser or more complex mirror configuration, mirror coating, obscuration, or optical design may be used than those shown and described herein. Embodiments of the invention may be applied to different reflective materials and constructions. Optical elements may be added to the system for a variety of different reasons. Therefore, the configurations may vary from implementation to implementation depending upon numerous factors, such as price constraints, performance requirements, technological improvements, or other circumstances. Embodiments of the invention may also be applied to other types of photolithography systems that use different materials and devices than those shown and described herein.

In the description above, numerous specific details are set forth. However, it is understood that embodiments of the invention may be practiced without these specific details. For example, well-known equivalent optical elements and materials may be substituted in place of those described herein. In other instances, well-known optical elements, structures and techniques have not been shown in detail to avoid obscuring the understanding of this description.

While the embodiments of the invention have been described in terms of several examples, those skilled in the art may recognize that the invention is not limited to the embodiments described, but may be practiced with modification and alteration within the spirit and scope of the appended claims. The description is thus to be regarded as illustrative instead of limiting.

What is claimed is:

1. An optical projection system for photolithography, the projection system comprising at least eight reflecting surfaces for imaging a reflection of a photolithography mask onto a wafer, the system having a numerical aperture of at least 0.5.

2. The optical projection system of claim 1, further comprising an obscuration in at least one reflecting surface to allow the reflection to pass through the obscuration.

3. The optical projection system of claim 1, wherein the obscuration is in the two reflecting surfaces closest to the wafer.

4. An optical projection system for photolithography, the projection system comprising at least eight reflecting surfaces for imaging a reflection of a photolithography mask onto a wafer, the angle of incidence of light reflecting from the mask to the wafer on each surface being no greater than 18 degrees.

5. The optical projection system of claim 4, comprising eight reflective surface, the two surfaces closest to the wafer including an obscuration to allow the reflection of the mask to pass through the respective obscurations.

6. The optical projection system of claim 4, wherein the reflective surfaces comprise a multilayer Mo/Si film.

7. An optical projection system for photolithography comprising at least eight reflecting surfaces for imaging a reflection of a photolithography mask onto a wafer, the seventh and eighth surfaces having an obscuration to allow an image to pass through the obscuration.

8. The system of claim 7, wherein the reflective surfaces form a first group to generate the first intermediate image, a second group to generate the second intermediate image, and a third group consisting of the seventh and eighth reflective surfaces, to relay the second intermediate image onto the wafer.

9. The optical projection system of claim 7, wherein seventh reflective surface is closer to the mask than the eighth reflective surface.

10. The optical projection system of claim 7, wherein the bbscurations are positioned so that diffracted orders of illumination at off-axis angles.

11. An optical system for photolithography comprising:
collection optics to produce an annular illumination pattern on a photolithography mask; and
projection optics having a reflective surface with an obscuration that coincides at least in part with the central portion of the annular illumination pattern.

12. The optical system of FIG. 11, wherein the projection optics comprise a plurality of reflective elements and wherein the two reflective elements closest to the image have an obscuration.

13. The optical projection system of claim 12, wherein the plurality of reflective elements comprise five positive power reflecting surfaces and three negative power reflecting surfaces.

14. An optical projection system for photolithography, the projection system, comprising at least eight reflecting surfaces for imaging a reflection of a photolithography mask onto a wafer, the projection system forming a first virtual image between the second and third reflective surfaces and a second virtual image between the sixth and seventh reflective surfaces.

15. The optical projection system of claim 14, wherein the first and second optical elements form an imaging group and the seventh and eighth optical elements form a relay group.

16. The optical projection system of claim 15, wherein the angles of incidence of light reflecting on each of six of the eight reflective surfaces is no greater than eight degrees.

17. An optical projection system for photolithography comprising at least eight reflecting surfaces for imaging a reflection of a photolithography mask onto a wafer, the eight reflecting surfaces being, from long conjugate to short conjugate,
a first mirror having a concave reflecting surface;
a second mirror
a third mirror;
a fourth mirror having a concave reflecting surface;
a fifth mirror having a convex reflecting surface
a sixth mirror having a concave reflecting surface;
a seventh mirror having a convex reflecting surface; and
an eight mirror having a concave reflecting surface.

18. The system of claim 17, wherein the second mirror has a convex reflecting surface and the third mirror has a concave reflecting surface.

19. The system of claim 17, wherein the second mirror has a concave reflecting surface and the third mirror has a convex reflecting surface.

20. The system of claim 17, wherein the reflective surfaces form a first group to generate a first intermediate image, a second group to generate a second intermediate image, and a third group to relay the second intermediate image onto the wafer.

21. The system of claim 17, wherein the angles of incidence of light reflecting on each of six of the eight reflective surfaces is no greater than eight degrees.
